(19) United States
(12) Patent Application Publication
(10) Pub. No.: US 2005/0253659 A1
(43) Pub. Date: Nov. 17, 2005

(54) Current-controlled quadrature oscillator using differential gm/C cells incorporating amplitude limiters

(76) Inventors: Pierre Favrat, Milpitas, CA (US); Didier Margairaz, San Jose, CA (US); Alain-Serge Porret, Sunnyvale, CA (US); Dominique Python, Sunnyvale, CA (US)

Correspondence Address: PATENT LAW GROUP LLP, 2635 NORTH FIRST STREET, SUITE 223, SAN JOSE, CA, 95134, US

(21) Appl. No.: 10/846,364

(22) Filed: May 14, 2004

(51) Int. Cl. H03B 1/00

(52) U.S. Cl. 331/57

(57) ABSTRACT

An oscillator includes a series of N number of gm/C stages where each gm/C stage has a pair of input terminals and a pair of output terminals. The pair of output terminals of each gm/C stage is coupled to the pair of input terminals of the next gm/C stage except the pair of output terminals of the last gm/C stage is cross-coupled to the pair of input terminals of the first gm/C stage whereby the oscillator oscillates in quadrature. Each gm/C stage includes a differential pair of transistors, a tunable current source, a capacitor, an amplitude limiter circuit and an active load and common mode bias circuit. The capacitor and the amplitude limiter circuit are coupled between the pair of output terminals of the gm/C stage. The amplitude limiter circuit operates to limit the voltage magnitude of the output signal at the pair of output terminals of the gm/C stage.

### FIELD OF THE INVENTION

The invention relates to a quadrature oscillator circuit and, in particular, to current-controlled quadrature oscillator circuit based on differential gm/C cells that each incorporates an amplitude limiter circuit.

### DESCRIPTION OF THE RELATED ART

A voltage controlled oscillator (VCO) is used in a television tuner to operate a mixer circuit for tuning the input RF signal to an IF signal having an intermediate frequency. Voltage controlled oscillators are known. VCO circuits can be implemented using LC tanks including a coil as the inductor having a fixed inductance and a capacitor variable capacitance. LC tanks usually have limited tunable range. Thus, the tunable frequency of the oscillator circuit cannot vary very much. The limited tunable range is due to the variable capacitor whose capacitance cannot vary very much.

However, in some application, it is desirable for the VCO circuit to have a very large tunable range, such as from near zero or a few MHz to about 1 GHz. Thus, the oscillator circuit must be capable of having its oscillating frequency change from a few MHz to 1 GHz. It is not practical to implement a VCO with a large tunable range using LC tanks because a large number of LC tanks will be needed, increasing the size and cost of the VCO circuit.

Another implementation of a VCO circuit uses a pair of gm/C cells, as shown in FIG. 1. In the oscillator circuit of FIG. 1, each gm/C cell contributes a 90 degree phase shift. A start-up circuit is usually required to ensure proper start-up of the oscillator circuit.

### SUMMARY OF THE INVENTION

According to one embodiment of the present invention, an oscillator includes a series of N number of gm/C stages where N is an even number. Each gm/C stage has a pair of input terminals and a pair of output terminals. The pair of output terminals of each gm/C stage is coupled to the pair of input terminals of the next gm/C stage except the pair of output terminals of the last gm/C stage is cross-coupled to the pair of input terminals of the first gm/C stage whereby the oscillator oscillates in quadrature. Each gm/C stage includes a differential pair of transistors, a tunable current source, a capacitor, an amplitude limiter circuit and an active load and common mode bias circuit. Each transistor in the differential pair of transistors has a control terminal and first and second current handling terminals. The control terminals of the differential pair is the pair of input terminals of the gm/C stage, the first current handling terminals of the differential pair is connected together and the second current handling terminals of the differential pair is the pair of output terminals of the gm/C stage. The tunable current source is coupled to the first current handling terminals of the differential pair of transistors for providing a tunable current to bias the differential pair. The capacitor and the amplitude limiter circuit are coupled between the second current handling terminals of the differential pair. The active load and common mode bias circuit coupled between a first power supply voltage and the second current handling terminals of the differential pair. The amplitude limiter circuit operates to limit the voltage magnitude of the output signal at the pair of output terminals of the gm/C stage.

The present invention is better understood upon consideration of the detailed description below and the accompanying drawings.

### BRIEF DESCRIPTION OF THE DRAWINGS

FIG. 1 illustrates a conventional quadrature oscillator circuit implemented using gm/C cells.

FIG. 2 is a circuit diagram of a current-controlled quadrature oscillator according to one embodiment of the present invention.

FIG. 3 is a circuit diagram of a gm/C stage according to one embodiment of the present invention.

FIG. 4 is a circuit diagram of a gm/C cell according to an alternate embodiment of the present invention.

FIG. 5 illustrates an input signal waveform and an output signal waveform of the gm/C stage of FIG. 3 or 4.

FIG. 6 is a circuit diagram of the gm/C stage of FIG. 3 and illustrates the implementation of the amplitude limiter circuit as a pair of back-to-back connected diode according to a first embodiment of the present invention.

FIG. 7 is a circuit diagram of the gm/C stage of FIG. 4 and illustrates the implementation of the amplitude limiter circuit as a pair of back-to-back connected diodes according to a first embodiment of the present invention.

FIG. 8 is a circuit diagram of the amplitude limiter circuit according to a second embodiment of the present invention.

FIG. 9 illustrates circuits which can be used to construct the switch in the amplitude limiter circuit in FIG. 8 and FIG. 10.

FIG. 10 is a circuit diagram of the amplitude limiter circuit according to a third embodiment of the present invention.

FIG. 11 illustrates an output signal waveform of a gm/C stage implementing the variable-amplitude amplitude limiter circuit of FIGS. 8 and 9.

FIG. 12 illustrates circuits which can be used to construct the tunable current source of the gm/C cell in FIG. 3 and FIG. 4.

FIG. 13 is a circuit diagram of an active load and common mode bias circuit according to one embodiment of the present invention.

FIGS. 14 and 15 illustrate two embodiments of a start-up circuit which can be incorporated in the gm/C stage of the present invention.

FIG. 16 is a circuit diagram of a current-controlled quadrature oscillator providing quasi-sinusoidal output signals according to one embodiment of the present invention.

FIG. 17 is a circuit diagram of a divider circuit which can be incorporated in the oscillator of FIG. 16.

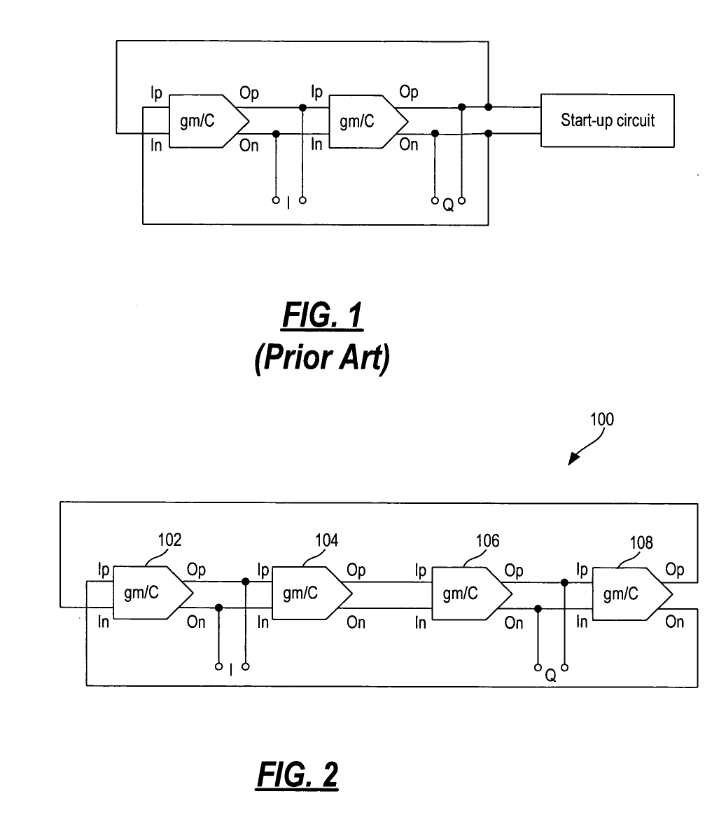

### DETAILED DESCRIPTION OF THE PREFERRED EMBODIMENTS

In accordance with the principles of the present invention, a current-controlled quadrature oscillator uses differential gm/C cells where each gm/C cell incorporates an amplitude limiter circuit. The gm/C cell (stage) includes a differential pair of transistors, a tunable current source, a capacitor and the amplitude limiter circuit for limiting the amplitude of the oscillation. An active load and common-mode biasing circuit is coupled to the differential pair for biasing the gm/C stage. The current-controlled quadrature oscillator of the present invention including multiple gm/C cells has an extended tunable frequency range so that a large frequency range of interest can be covered using a single circuit block.

Another advantage of the current-controlled quadrature oscillator of the present invention is that the oscillator circuit does not require a start-up circuit or negative resistance to assist in the circuit start-up. This is because the total phase shift of the feedback loop of the quadrature oscillator can be made to be more than 360 degrees and thus proper start-up of the oscillator is ensured. In one embodiment, four gm/C stages are interconnected in a feedback loop to form a quadrature oscillator where each gm/C stage contributes at least a 45 degree phase shift to the oscillating frequency. The last one of the gm/C stages is configured to contribute a slightly greater than 45 degree phase shift. The current-controlled quadrature oscillator thus assures that the total phase shift of the feedback loop is more than 360 degrees and the oscillator circuit will oscillate upon start-up without external start-up biasing. By eliminating the requirement for a start-up circuit, the quadrature oscillator of the present invention can be implemented in a small footprint, thereby reducing the size of the oscillator circuit and the associated manufacturing cost.

FIG. 2 is a circuit diagram of a current-controlled quadrature oscillator according to one embodiment of the present invention. Referring to FIG. 2, an oscillator 100 includes a series of gm/C cells (stages) connected in a cross-coupled feedback loop so that the oscillator oscillates in quadrature. Oscillator 100 provides an “in-phase” output signal I and a “quadrature-phase” output signal Q. In the present embodiment, quadrature oscillator 100 includes four gm/C stages 102-108. In the present description, a gm/C cell or stage refers to an integrator stage having the transfer function Vout(s)=Vin(s)/sC. Each gm/C stage includes a pair of input terminals: positive input terminal Ip and negative input terminal In; and a pair of output terminals: positive output terminal Op and negative output terminal On. The output terminals of the last gm/C stage 108 is cross-coupled to the input terminals of the first gm/C stage 102, forming the feedback loop. Specifically, the positive output terminal of gm/C stage 108 is coupled to the negative input terminal of gm/C stage 102 while the negative output terminal of gm/C stage 108 is coupled to the positive input terminal of gm/C stage 102. The output terminals of the first gm/C cell 102 provide the positive and negative “in-phase” signals (I) and the output terminals of the third gm/C cell 106 provide the positive and negative quadrature signals (Q).

In the present embodiment, each of the gm/C stages contributes at least a “nominal” amount of phase shift to the feedback loop. In the present description, when N gm/C stages are used, the “nominal” amount of phase shift is 180/N. Thus, when four gm/C stages are used (N−4), each gm/C stage has at least a 45 degree phase shift between a signal appearing on the input terminals and a signal appearing on the output terminals of the gm/C stage. When four gm/C stages each contributing a 45 degree phase shift are connected in series, a total phase shift of 180 degree phase shift results. A further 180 degree phase shift results from the cross-coupling of the first and last gm/C stages to form the feedback loop so that a 360 degree phase shift is realized for the feedback loop.

In oscillator 100, by cross coupling the output terminals of the last gm/C stage 108 and the input terminals of the first gm/C stage 102, the gm/C stages are caused to oscillate in quadrature. Thus, a signal appearing on the input terminals of the first gm/C stage 102 is 180 degrees out of phase with the corresponding signal appearing on the output terminals of the last gm/C stage 108 and the oscillator thereby oscillates. The in-phase and quadrature-phase output signals are thus generated.

In accordance with the present invention, the phase shift contribution of one of the gm/C stage is made to be slightly greater than the nominal phase shift value to ensure that the total phase shift of the feedback loop is greater than 360 degrees. When the total phase shift of the feedback loop is greater than 360 degrees, the oscillator is guaranteed to start-up and a separate start-up circuit is not required. In the embodiment shown in FIG. 2, each of gm/C stages 102, 104, 106 provides a phase shift of 45 degrees while the last gm/C stage 108 provides a phase shift of 48 degrees. Therefore, the total phase shift of the oscillator feedback loop is slightly greater than 360 degrees and oscillator 100 is guaranteed to start-up without external start-up circuit.

In the embodiment shown in FIG. 2, a series of four gm/C stages is used. In other embodiments, other even number of gm/C stages can be used to implement the quadrature oscillator. The phase shift provided by each gm/C stage in a series of N gm/C stages should be at least 180°/N. The phase shift provided by one of the N gm/C stages is purposely made to be slightly greater than 180°/N so that the total phase shift is slightly greater than 360 degrees. The one gm/C stage with the slightly larger phase shift can be any of the series of gm/C stages and does not need to be the last gm/C stage. As is well understood in the art, when the in-phase output signal is taken from the output terminals of a first gm/C stage in the series of N gm/C stages, the quadrature-phase output signal is provided by the output terminals of a gm/C stage 90° phase shift away from the first gm/C stage.

FIG. 3 is a circuit diagram of a gm/C stage according to one embodiment of the present invention. Referring to FIG. 3, a gm/C stage 140 includes a differential pair of NPN bipolar transistors Q1 and Q2. The base terminals (nodes 146, 148) of the transistors Q1 and Q2 form the respective positive and negative input terminals (Ip, In) of the gm/C stage. The differential pair of transistors Q1 and Q2 is biased by a tunable current source 156 providing a tunable current Itune. Tunable current source 156 is coupled between the emitter terminals (node 157) of transistors Q1 and Q2 and a negative power supply voltage (node 144) which is the ground potential in the present embodiment. The collector terminals (nodes 150 and 152) of transistors Q1 and Q2 form the respective negative and positive output terminals (On, Op) of the gm/C stage.

The gm/C stage also includes a capacitor C1 coupled between the collector terminals (nodes 150 and 152) of transistors Q1 and Q2. The time constant of the gm/C stage and thus the phase shift contribution of the gm/C stage are a function of the transconductance (gm) of the bipolar transistors (Q1, Q2) and the capacitance of the capacitor C1. The time constant T of the gm/C stage can be expressed as C1/gm. By selecting an appropriate transconductance (gm) for the bipolar transistors and an appropriate capacitance value for capacitor C1, the desired amount of phase shift between a signal appearing on the input terminals and a signal appearing on the output terminals can be produced. In the present embodiment, the transconductance (gm) of transistors Q1, Q2 and the capacitance of the capacitor C1 produce a 45 degree phase shift.

In gm/C stage 140, an active load and common mode bias circuit 158 provides loading and common mode biasing to the differential pair of transistors Q1 and Q2. Active load circuit 158 includes a pair of common-mode terminals which are coupled to the pair of output terminals (nodes 150, 152) of the differential pair. Active load circuit 158 is connected to a positive power supply voltage Vs1 which in the present case is the Vdd voltage. Various embodiments of the active load and common mode bias circuit are possible and will be described in more detail below.

In accordance with the present invention, gm/C stage 140 further includes an amplitude limiter circuit 154 for controlling and limiting the amplitude of the quadrature oscillator signals. The amplitude limiter circuit, also referred to as a clamp circuit, is coupled between the output nodes of the differential pair. That is, amplitude limiter circuit 154 is connected between the negative output terminal (node 150) and the positive output terminal (node 152) of gm/C stage 140. Amplitude limiter circuit 154 operates to limit the voltage amplitude of the signals on the output nodes of the differential pair to a predetermined value Vp established by the amplitude limiter circuit. By limiting the voltage amplitude of the signals on the output nodes of the differential pair, the current source in the active load and common mode bias circuit 158 is prevented from becoming saturated. The performance of gm/C cell 140 is thus improved.

The operation of gm/C stage 140 and, in particular, the operation of the amplitude limiter circuit 154 in the gm/C stage is illustrated in the signal waveforms of FIG. 5. In FIG. 5, the input signal waveform is assumed to be a sinusoidal waveform. The gm/C integrator stage integrates the charge associated with the input sinusoidal waveform and converts the waveform to a triangular wave. The peak-to-peak amplitude of the would-be triangular wave output is limited to a voltage Vp established by the amplitude limiter circuit. Thus, the output waveform of the gm/C stage is a trapezoidal waveform as shown in the bottom waveform of FIG. 5.

By using an amplitude limiter circuit in the gm/C stage, unwanted harmonics in the output signal can be significantly reduced. In conventional oscillator systems, the input waveform assumes a square wave and produces a −10 dB third harmonic. When the input waveform is converted to a triangular output waveform, a −20 dB third harmonic results. In accordance with the present invention, when the gm/C cell provides a trapezoidal waveform as the output signal, the unwanted harmonics are significantly reduced compared to the triangular waveform. The harmonic content is reduced significantly with a trapezoidal waveform due to its closer approximation to a sine wave. The quadrature oscillator of the present invention is particular useful for constructing a quadrature phase Voltage Controlled Oscillator (VCO). By generating a trapezoidal waveform as output signals, the oscillator can reduce significantly unwanted harmonics in the output spectrum. By varying the current Itune in the tunable current source of each gm/C stage, the gm/C cells can be used to construct a tunable quadrature oscillator where an inversion or a 180 degree phase shift in the loop is produced.

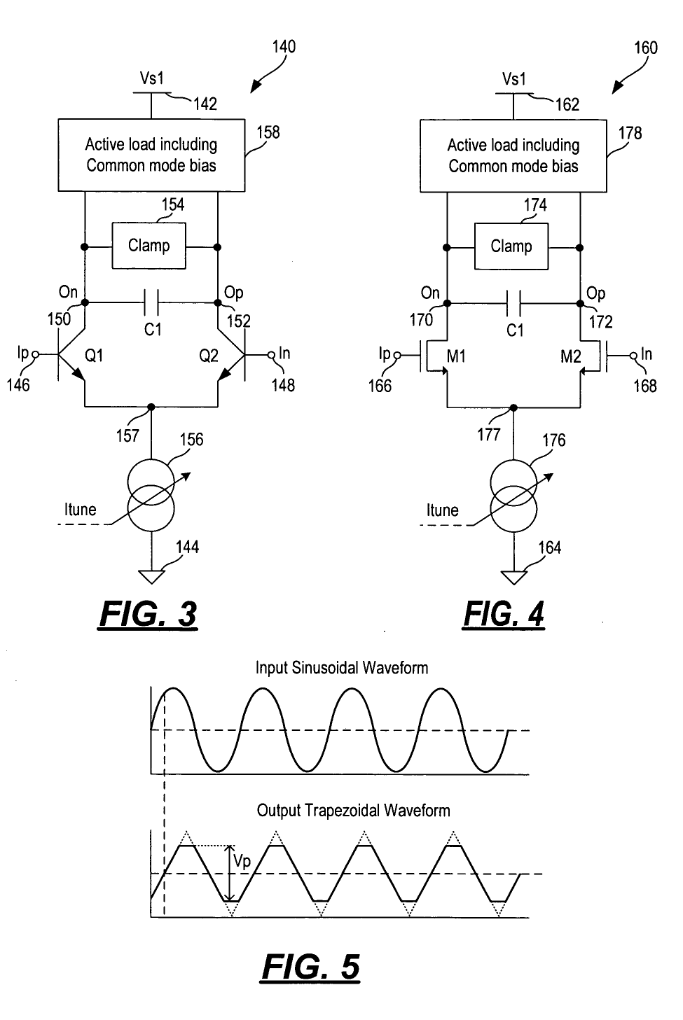

In gm/C cell 140 of FIG. 3, the differential pair is formed using bipolar transistors. However, the differential pair can be formed using other types of transistors that provide the desired transconductance value. FIG. 4 is a circuit diagram of a gm/C cell according to an alternate embodiment of the present invention. In FIG. 4, the gm/C stage 160 is constructed in the same manner as gm/C stage 140 of FIG. 3 except that the differential pair is formed using NMOS transistors M1 and M2. An amplitude limiter circuit or a clamp circuit 174 is connected between the negative output terminal On (node 170) and the positive output terminal Op (node 172) of gm/C stage 160. The operation of gm/C stage 160 is analogous to that of gm/C stage 140 for providing trapezoidal output signals at the drain terminals (nodes 170, 172) of transistors M1 and M2 where the amplitude of the trapezoidal output signals is limited by a voltage Vp established by amplitude limiter circuit 174.

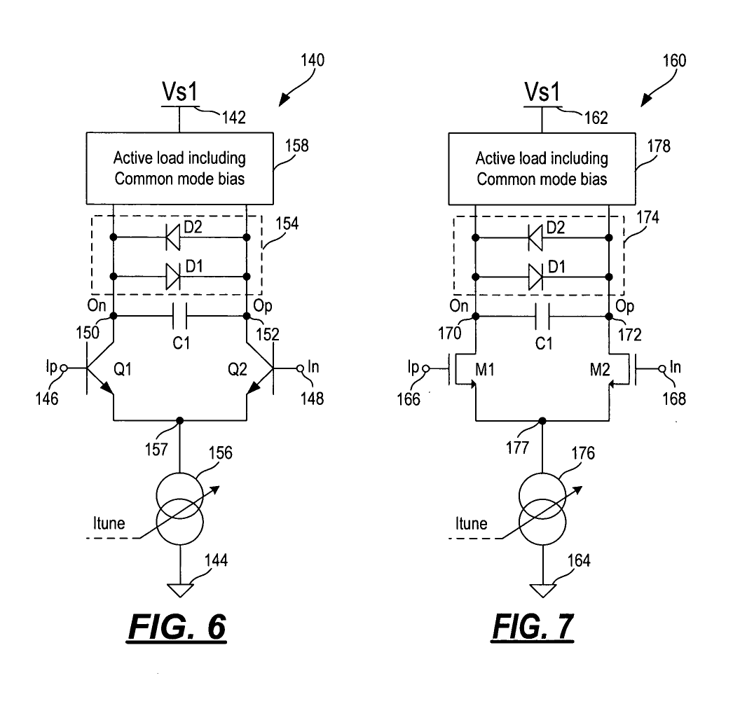

The amplitude limiter circuit of the present invention can be configured in various forms to clamp the voltage of the output signals of the gm/C stage to the desired voltage value. In a first embodiment, the amplitude limiter circuit is implemented as a pair of back-to-back connected diodes as shown in FIG. 6. FIG. 6 is a circuit diagram of the gm/C stage of FIG. 3 and illustrates the implementation of amplitude limiter circuit 154 as a pair of back-to-back connected diodes. Referring to FIG. 6, a diode D1 and a diode D2 are connected between the output terminal (nodes 150 and 152) of the gm/C stage. Diodes D1 and D2 are connected back-to-back. That is, the anode of diode D1 is connected to node 150 while the cathode is connected to node 152. On the other hand, the anode of diode D2 is connected to node 152 while the cathode is connected to node 150. As thus configured, diodes D1 and D2 limit the voltage between the output terminals of the differential pair of bipolar transistors to within one diode voltage drop Vd (that is, voltage Vp in FIG. 5 is equal to voltage Vd). Diodes D1 and D2 can be implemented as p-n junction diodes or as diode-connected bipolar or MOS transistors.

FIG. 7 is a circuit diagram of the gm/C stage of FIG. 4 and illustrates the implementation of the amplitude limiter circuit as a pair of back-to-back connected diodes in the same manner as in FIG. 6 above. That is, a diode D1 and a diode D2 are connected back-to-back between the output terminal (nodes 170 and 172) of the gm/C stage. Diodes D1 and D2 limit the voltage between the output terminals of the differential pair of bipolar transistors to within one diode voltage drop Vd.

In the implementations shown in FIGS. 6 and 7, the amplitude limit of the amplitude limiter circuit is a fixed voltage—the diode voltage drop Vd. In some applications, it is desirable to provide an amplitude limiter circuit where the voltage amplitude limit can be varied. By adjusting the voltage amplitude of the output signal waveform, the trapezoidal output signal can be modified to approximate a sinusoidal waveform as close as possible. Thus, when the voltage amplitude of the output signal waveform is varied, the harmonic content of the output signal is modified accordingly. Specific voltage amplitude can be thus selected to minimized specific unwanted harmonics.

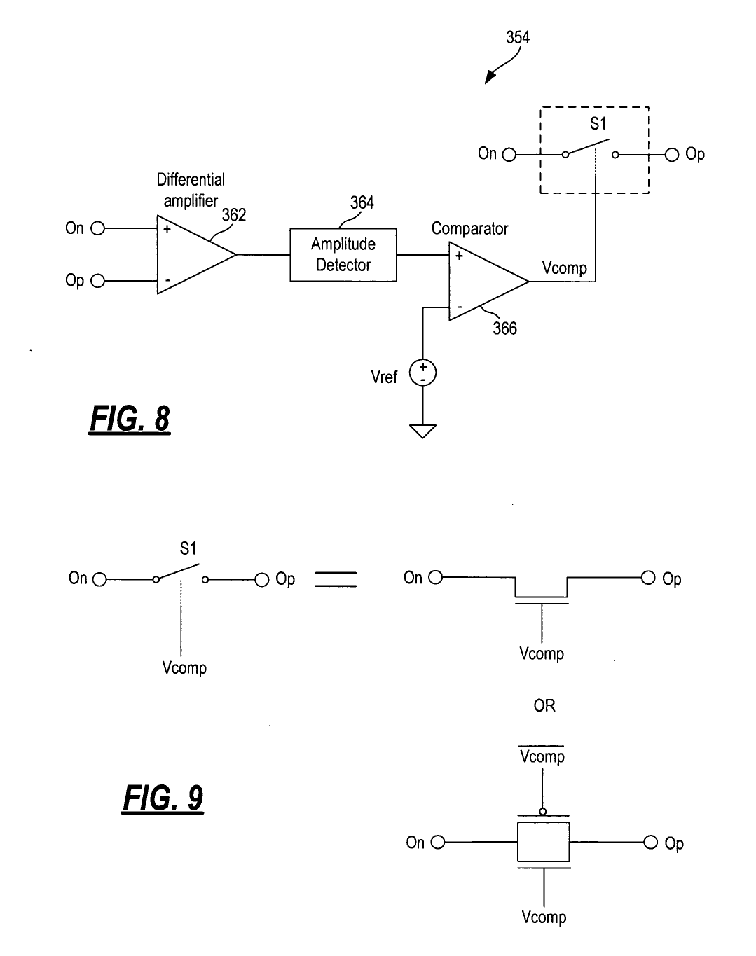

Accordingly, in a second embodiment of the amplitude limiter circuit of the present invention, output voltage clamping in the gm/C stage is provided by a switch where the switch control signal is the voltage difference between the output signal voltage amplitude and a reference voltage Vref. FIG. 8 is a circuit diagram of the amplitude limiter circuit according to the second embodiment of the present invention. When the amplitude limiter circuit in FIG. 8 is used, the output signal voltage amplitude is clamped at the reference voltage Vref level. The clamping voltage of the amplitude limiter circuit can be varied by adjusting the reference voltage Vref.

Referring to FIG. 8, amplitude limiter circuit 354 includes a switch S1 connected between the negative output terminal (On) and the positive output terminal (Op) of a gm/C stage. When switch S1 is closed, the negative output terminal and the positive output terminal are shorted together and the voltage amplitude of output signal is thus clamped. The control voltage Vcomp of switch S1 is generated as follows. A differential amplifier 362 is coupled to the negative output terminal (On) and the positive output terminal (Op) of a gm/C stage. Differential amplifier 362 thus measures the peak-to-peak amplitude of the output signal on the negative and positive output terminals of the gm/C stage. An amplitude detector 364 is coupled to receive the output signal from differential amplifier 362 and provides an amplitude output signal. Because the output signal of the gm/C stage is an oscillating signal, the peak-to-peak amplitude of the output signal measured by differential amplifier 362 will have alternating positive and negative signs associated with the peaks or valleys of the oscillating signal. Amplitude detector 362 operates to convert the positive/negative amplitude measurement to an absolute value of the amplitude measurement. That is, amplitude detector 362 provides an amplitude output signal indicative of the magnitude of the output signal amplitude measured by differential amplifier 362.

In amplitude limiter circuit 354, a comparator 366 compares the amplitude output signal of amplitude detector 364 to a reference voltage Vref. When the value of the amplitude output signal is greater than the reference voltage Vref, the control signal Vcomp is asserted to close switch S1. The amplitude of the output signal of the gm/C stage is thus clamped. When the value of the amplitude output signal is equal to or smaller than the reference voltage Vref, the control signal Vcomp is deasserted to open switch S1. The amplitude of the output signal of the gm/C stage is thus allowed to vary.

Switch S1 can be implemented in a conventional manner for providing a switchable connection between two nodes based on a control voltage. In one embodiment, switch S2 is implemented as a MOS switch or a transmission gate as shown in FIG. 9.

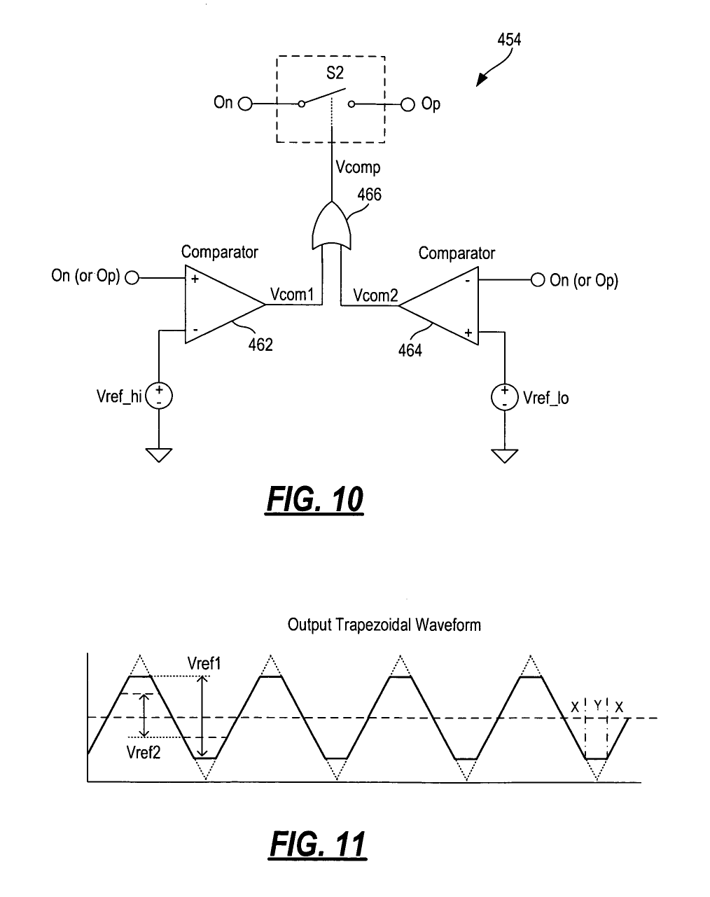

In a third embodiment of the amplitude limiter circuit of the present invention, output voltage clamping is providing by a switch where the switch control signal is the voltage difference between the maximum and minimum output voltage levels and a reference voltage Vref. FIG. 10 is a circuit diagram of the amplitude limiter circuit according to the third embodiment of the present invention. Similar to the circuit of FIG. 8, the clamping voltage of the amplitude limiter circuit of FIG. 10 can be varied by adjusting the reference voltage Vref.

Referring to FIG. 10, amplitude limiter circuit 354 includes a switch S2 connected between the negative output terminal (On) and the positive output terminal (Op) of a gm/C stage. When switch S2 is closed, the negative output terminal and the positive output terminal are shorted together and the voltage amplitude of output signal is thus clamped. The control voltage Vcomp of switch S2 is generated as follows. The signal on either the negative output terminal (On) or the positive output terminal (Op) is coupled to a comparator 462 to be compared with a high level reference voltage Vref_hi. The same signal or a signal from the other output terminal is coupled to a second comparator 464 to be compared with a low level reference voltage Vref_lo. The output signals Vcom1 and Vcom2 of comparators 462 and 464 are coupled to an OR gate 466. The output signal of OR gate 466, the logical OR of signals Vcom1 and Vcom2, is the control voltage Vcomp for switch S2.

In operation, when the signal on the negative output terminal (On) or the positive output terminal (Op) is greater than the Vref_hi signal, output signal Vcom1 is asserted. OR gate 466 asserts output signal Vcomp accordingly and switch S2 is closed. The voltage amplitude of the output signal of the gm/C stage is thus limited at a high level to the high level reference voltage Vref_hi. When the signal on the negative output terminal (On) or the positive output terminal (Op) is less than the Vref_lo signal, output signal Vcom2 is asserted. OR gate 466 asserts output signal Vcomp accordingly and switch S2 is closed. The voltage amplitude of the output signal of the gm/C stage is thus limited at a low level to the low level reference voltage Vref_lo. When the signal on the negative output terminal (On) or the positive output terminal (Op) is between voltage Vref_hi and voltage Vref_lo, neither output signal Vcom1 or Vcom2 is asserted and OR gate 466 output Vcomp is also deasserted. Switch S2 is thus open to allow the output signal to oscillate. Switch S2 can be implemented in any conventional manner as described above with reference to switch S1 of FIG. 8. For instance, switch S2 can be implemented as a MOS transistor or as a transmission gate as shown in FIG. 9.

The amplitude limiter circuits of FIGS. 8 and 9 have particular applications in the gm/C stage of the present invention. Specifically, amplitude limiter circuit 354 of FIG. 8 can be applied in an gm/C stage where the common mode bias circuit of the gm/C is unregulated. That is, the common mode bias circuit does not include a feedback loop. When the common mode bias circuit is unregulated, an absolute reference for the positive and negative output voltages is not known. Therefore, a differential amplifier is used in amplitude limiter circuit 354 to measure the difference between the high and low voltage levels of the output signal of the gm/C stage to determine the amplitude of the output signal. On the other hand, where the common mode bias circuit is regulated, amplitude limiter circuit 454 of FIG. 10 can be applied instead. When the common mode bias circuit is regulated, the reference voltage of the output signal is known and thus the absolute value of the voltage levels of the output signal can be used to determine the signal amplitude and apply clamping. A differential amplifier is not required.

FIG. 11 illustrates an output signal waveform of an gm/C stage implementing the variable-amplitude amplitude limiter circuit of FIGS. 8 and 9. Referring to FIG. 11, the amplitude of the trapezoidal waveform can be varied by adjusting the reference voltage level. A change in the reference voltage (Vref or Vref_hi/Vref_lo) results in a change in the waveform shape and consequently a change in the harmonic content of the output signal. Thus, by adjusting the voltage at which the output signal is clamped, the harmonic content of the output signal can be varied so that a specific undesired harmonic can be minimized. For instance, in FIG. 11, the duration of the flat area of the trapezoidal waveform is denoted by “Y” while the duration of the sloped area of the trapezoidal waveform is denoted by “X”. A ratio “a” can be defined as: a=X/Y. If a=1, the third harmonic is minimized. If a=2, then the fifth harmonic is minimized. If a=3, the seventh harmonic is minimized, and so on. In one embodiment, a is selected to be 1.4 where both the third and the fifth harmonic is minimized.

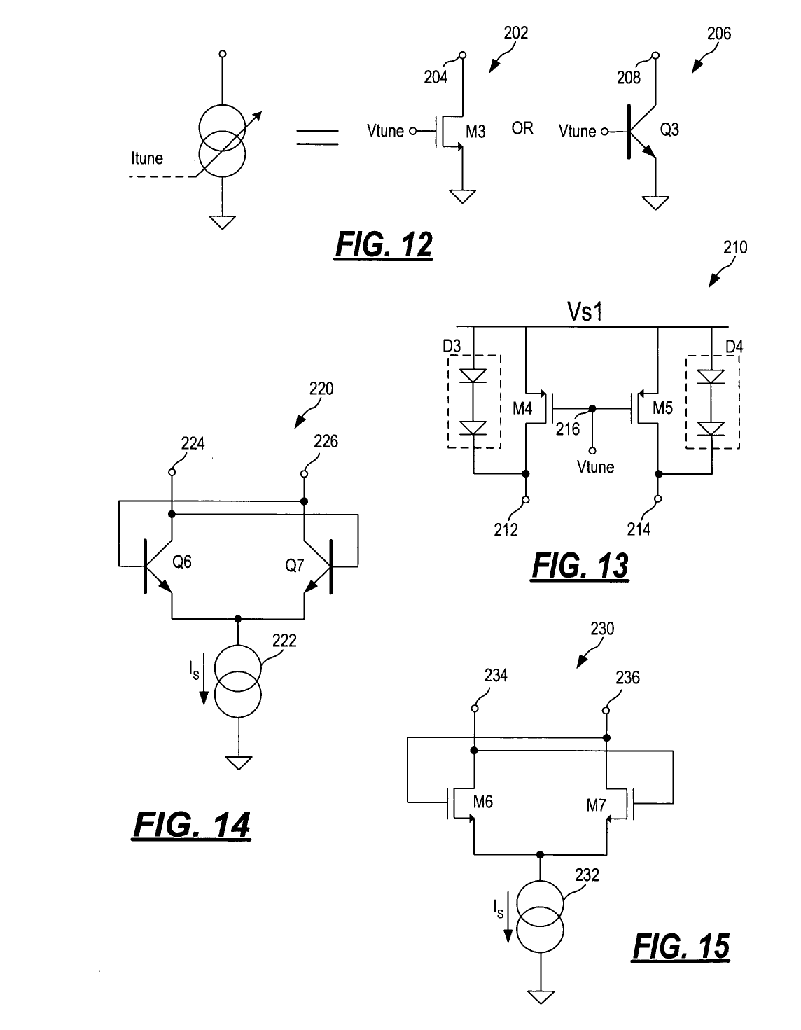

FIG. 12 illustrates circuits which can be used to construct the tunable current source (156, 176) of gm/C cell 140 (FIG. 3) and gm/C cell 160 (FIG. 4). Referring to FIG. 12, a first embodiment of the tunable current source 202 uses an NMOS transistor M3. A tuning voltage Vtune is coupled to the gate terminal of transistor M3 while the source terminal is coupled to the negative power supply voltage (such as the ground voltage). A current Itune is thus provided at the drain terminal (node 204) of tunable current source 202. A second embodiment of the tunable current source 206 uses an NPN bipolar transistor Q3. A voltage Vtune is coupled to the base terminal of transistor Q3 while the emitter terminal is coupled to the negative power supply voltage (such as the ground voltage). A current Itune is thus provided at the collector terminal (node 208) of tunable current source 206. Of course, other circuit implementations can be used to construct the tunable current source in the gm/C cell of the present invention for providing a source of tunable current.

FIG. 13 is a circuit diagram of an active load and common mode bias circuit according to one embodiment of the present invention. Referring to FIG. 13, active load and common mode bias circuit 210 includes a diode chain D3 connected between the positive power supply voltage Vs1 and the common mode bias terminal 212. Diode chain D3 can include a single diode or a series of two or more diodes. Furthermore, diode chain D3 can be implemented as a p-n junction diode or as a diode-connected MOS or bipolar transistor, as is well known in the art. Diode chain D3 is connected in parallel with a PMOS transistor M4 where the gate terminal of transistor M4 is controlled by a voltage Vtune. The voltage Vtune is the same voltage for controlling the tunable current source and operates to adjust the drain current provided by transistor M4. Active load and common mode bias circuit 210 further includes a diode chain D4 connected between the positive power supply voltage Vs1 and the common mode bias terminal 214. Diode chain D4 is constructed in the same manner as diode chain D3. A PMOS transistor M5 is connected in parallel to diode chain D4 where the gate terminal of the transistor is also controlled by voltage Vtune.

The active load and common mode bias circuit shown in FIG. 13 is illustrative only and is not intended to limit the active load circuit of the gm/C stage of the present invention to circuit 210 of FIG. 13 only. Other embodiments of the active load circuit can also be used in the gm/C cell. For example, transistors M4 and M5 can be implemented as PNP bipolar transistors. Furthermore, the active load circuit can be implemented as a resistive load circuit and a current mirror circuit. Other circuit configurations for the active load/common mode bias circuit are described in U.S. Pat. No. 5,489,878 which patent is incorporated herein by reference in its entirety.

FIGS. 14 and 15 illustrate two embodiments of a start-up circuit which can be incorporated in the gm/C stage of the present invention. As described above, the oscillator constructed using gm/C stages of the present invention is capable of reliable start-up operation due to a total phase shift of greater than 360 degrees. Thus, a start-up circuit is not necessary. However, should a start-up circuit be desired, the start-up circuits in FIGS. 14 and 15 can be used. Of course, other start-up circuit configurations, such as circuits providing a negative resistance, can also be used in conjunction with the gm/C stage of the present invention.

In FIG. 14, a start-up circuit 220 includes a cross-coupled differential pair of NPN bipolar transistors Q6 and Q7. A current source 222 is connected to the emitter terminals of transistors Q6 and Q7. Terminals 224, 226 are to be coupled to the output terminals (150/152 or 170/172) of the gm/C stage. The current Is of current source 222 is selected to give the desired negative resistance for starting up the gm/C stage.

In FIG. 15, a start-up circuit 230 includes a cross-coupled differential pair of NMOS transistors M6 and M7. A current source 232 is connected to the source terminals of transistors M6 and M7. Terminals 234, 236 are to be coupled to the output terminals (150/152 or 170/172) of the gm/C stage. The current Is of current source 232 is selected to give the desired negative resistance for starting up the gm/C stage.

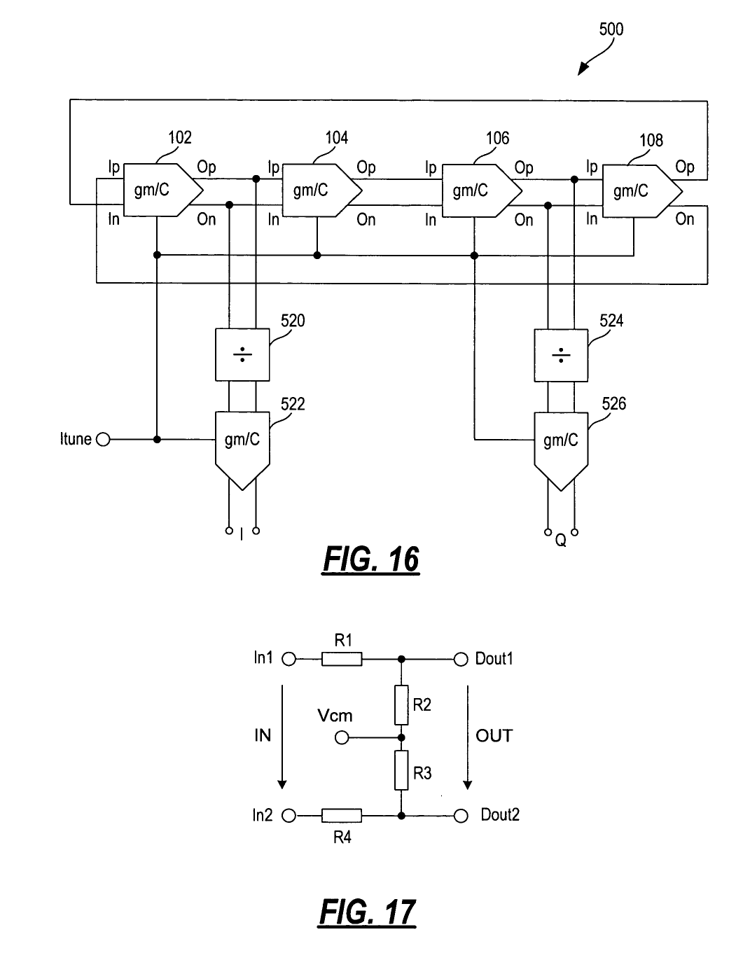

In some applications, a quasi-sinusoidal output signal is desired from the oscillator circuit. FIG. 16 is a circuit diagram of a current-controlled quadrature oscillator providing quasi-sinusoidal output signals according to one embodiment of the present invention. Referring to FIG. 16, an oscillator 500 includes a series of four gm/C stages connected in a cross-coupled feedback loop so that the oscillator oscillates in quadrature. An additional two gm/C stages are included at the in-phase and quadrature-phase output terminals to convert the trapezoidal output signal to a quasi-sinusoidal output signals. Specifically, a divider circuit 520 is coupled to the positive and negative output terminals of the first gm/C stage 102. The divider circuit steps down the voltage of the output signals on the positive and negative output terminals. The stepped down voltage is then provided to a gm/C stage 522. The gm/C stage is controlled by the same tunable current Itune that controls the gm/C stages in the feedback loop. The output signals from gm/C stage 522 is the in-phase quasi-sinusoidal output signal “I” of oscillator 500.

The quadrature-phase quasi-sinusoidal output signal “Q” is generated in the same manner. A divider circuit 524 is coupled to the positive and negative output terminals of the third gm/C stage 106. The stepped down voltage is then provided to a gm/C stage 526. The gm/C stage is controlled by the tunable current Itune that controls the gm/C stages in the feedback loop. The output signals from gm/C stage 526 is the quadrature-phase quasi-sinusoidal output signal “Q” of oscillator 500.

FIG. 17 is a circuit diagram of a divider circuit which can be incorporated in the oscillator of FIG. 16. The divider circuit operates to divide the voltage on the two input terminals relative to a common mode voltage Vcm. Referring to FIG. 17, a series of four resistive elements R1 to R4 is connected in series between the two input terminals of the divider circuit. The node between the second resistive element R2 and the third resistive element R3 is coupled to the common mode voltage Vcm. The first stepped-down voltage is provided at output terminal Dout1 and the second stepped-down voltage is provided at output terminal Dout2. The input voltage at the first input terminal In1 is stepped down by resistive elements R1 and R2 while the input voltage at the second input terminal In2 is stepped down by resistive elements R3 and R4.

The above detailed descriptions are provided to illustrate specific embodiments of the present invention and are not intended to be limiting. Numerous modifications and variations within the scope of the present invention are possible. The present invention is defined by the appended claims.

1. An oscillator comprising:
a series of N number of gm/C stages where N is an even number, each gm/C stage having a pair of input terminals and a pair of output terminals, the pair of output terminals of each gm/C stage is coupled to the pair of input terminals of the next gm/C stage except the pair of output terminals of the last gm/C stage is cross-coupled to the pair of input terminals of the first gm/C stage whereby the oscillator oscillates in quadrature,
wherein each gm/C stage comprises:
a differential pair of transistors, each transistor having a control terminal and first and second current handling terminals, the control terminals of the differential pair being the pair of input terminals, the first current handling terminals of the differential pair being connected together and the second current handling terminals of the differential pair being the pair of output terminals;
a tunable current source coupled to the first current handling terminals of the differential pair of transistors for providing a tunable current to bias the differential pair;
a capacitor coupled between the second current handling terminals of the differential pair;
an amplitude limiter circuit coupled between the second current handling terminals of the differential pair, the amplitude limiter circuit operative to limit the voltage amplitude of an output signal at the pair of output terminals to a first voltage level; and
an active load and common mode bias circuit coupled between a first power supply voltage and the second current handling terminals of the differential pair.

2. The oscillator of claim 1, wherein the pair of output terminals of a first selected gm/C stage in the series of N gm/C stages provides an in-phase output signal and the pair of output terminals of a second selected gm/C stage provides a quadrature-phase output signal, the second selected gm/C stage being a gm/C stage 90° phase shift away from the first selected gm/C stage.

3. The oscillator of claim 1, wherein the series of N number of gm/C stages comprises a series of four gm/C stages, the pair of output terminals of the first gm/C stage providing an in-phase output signal and the pair of input terminals of the last gm/C stage providing a quadrature-phase output signal.

4. The oscillator of claim 1, wherein each of the series of gm/C stages contributes at least 180/N degree of phase shift to the feedback loop formed by the gm/C stages.

5. The oscillator of claim 4, wherein a selected one of the series of gm/C stages contributes slightly greater than 180/N degree of phase shift to the feedback loop formed by the gm/C stages.

6. The oscillator of claim 1, wherein the series of N number of gm/C stages comprises a series of four gm/C stages, each of the gm/C stages contributes at least 45 degree of phase shift to the feedback loop formed by the gm/C stages.

7. The oscillator of claim 4, wherein a selected one of the series of gm/C stages contributes about 48 degree of phase shift to the feedback loop formed by the gm/C stages.

8. The oscillator of claim 7, wherein the selected one of the series of gm/C stages comprises the last one of the series of gm/C stages.

9. The oscillator of claim 1, wherein the differential pair of transistor comprise a differential pair of bipolar transistors, each bipolar transistor including a base terminal as the control terminal, an emitter terminal as the first current handling terminal and a collector terminal as the second current handling terminal.

10. The oscillator of claim 1, wherein the differential pair of transistor comprise a differential pair of MOS transistors, each MOS transistor including a gate terminal as the control terminal, a source terminal as the first current handling terminal and a drain terminal as the second current handling terminal.

11. The oscillator of claim 1, wherein the amplitude limiter circuit comprises a first diode and a second diode coupled back-to-back between the second current handling terminals of the differential pair, the first diode having an anode coupled to the second current handling terminal of a first transistor of the differential pair and a cathode coupled to the second current handling terminal of a second transistor of the differential pair, and the second diode having an anode coupled to the second current handling terminal of the second transistor of the differential pair and a cathode coupled to the second current handling terminal of the first transistor of the differential pair, the first voltage level being a diode voltage drop.

12. The oscillator of claim 11, wherein the first diode and the second diode each comprises a p-n junction diode.

13. The oscillator of claim 11, wherein the first diode and the second diode each comprises a diode connected bipolar transistor.

14. The oscillator of claim 11, wherein the first diode and the second diode each comprises a diode connected MOS transistor.

15. The oscillator of claim 1, wherein the amplitude limiter circuit comprises:
a switch coupled between the second current handling terminal of a first transistor of the differential pair and the second current handling terminal of a second transistor of the differential pair, the switch being controlled by a switch control signal;
a differential amplifier having a positive input terminal coupled to the second current handling terminal of the first transistor of the differential pair and a negative input terminal coupled to the second current handling terminal of the second transistor of the differential pair, the differential amplifier providing an output signal;
an amplitude detector coupled to receive the output signal of the differential amplifier and providing an output signal indicative of the magnitude of the output signal of the differential amplifier; and
a comparator having a first input terminal coupled to receive the output signal of the amplitude detector and a second input terminal coupled to receive a reference voltage, the comparator providing an output signal as the switch control signal for the switch,
wherein the first voltage level being the reference voltage.

16. The oscillator of claim 15, wherein the switch comprises a MOS transistor.

17. The oscillator of claim 15, wherein the switch comprises a transmission gate.

18. The oscillator of claim 1, wherein the amplitude limiter circuit comprises:
a switch coupled between the second current handling terminal of a first transistor of the differential pair and the second current handling terminal of a second transistor of the differential pair, the switch being controlled by a switch control signal;
a first comparator having a first input terminal coupled to one of the second current handling terminals of the differential pair and a second input terminal coupled to a first reference voltage, the first comparator providing a first output signal;
a second comparator having a first input terminal coupled to one of the second current handling terminals of the differential pair and a second input terminal coupled to a second reference voltage, the second comparator providing a second output signal; and
a logic gate performing a logical “OR” operation between the first output signal and the second output signal, the logic gate providing the switch control signal for the switch,
wherein the first voltage level being the voltage difference between the first reference voltage and the second reference voltage.

19. The oscillator of claim 18, wherein the switch comprises a MOS transistor.

20. The oscillator of claim 18, wherein the switch comprises a transmission gate.

21. The oscillator of claim 1, wherein the tunable current source comprises a MOS transistor having a gate terminal coupled to a tuning voltage, a source terminal coupled to a second power supply voltage and a drain terminal coupled to the first current handling terminals of the differential pair.

22. The oscillator of claim 1, wherein the tunable current source comprises a bipolar transistor having a base terminal coupled to a tuning voltage, an emitter terminal coupled to a second power supply voltage and a collector terminal coupled to the first current handling terminals of the differential pair.

23. The oscillator of claim 2, further comprising:
a first divider circuit coupled to the pair of output terminals of the first selected gm/C stage, the first divider circuit generating a first stepped-down output signal;
a first output gm/C stage coupled to receive the first stepped-down output signal and providing an quasi-sinusoidal in-phase output signal of the oscillator circuit at the pair of output terminals of the first output gm/C stage;
a second divider circuit coupled to the pair of output terminals of the second selected gm/C stage, the second divider circuit generating a second stepped-down output signal; and
a second output gm/C stage coupled to receive the second stepped-down output signal and providing an quasi-sinusoidal quadrature-phase output signal of the oscillator circuit at the pair of output terminals of the second output gm/C stage,
wherein the first and second output gm/C stages are constructed in the same manner as a gm/C stage of the series of N number of gm/C stages, the tunable current of the first and second output gm/C stages having the same magnitude as the tunable current in the series of N number of gm/C stages.

24. The oscillator of claim 23, wherein each of first and second divider circuits comprises:
a first input terminal and a second input terminal coupled to the pair of output terminals of the respective gm/C stage;
a series of four resistive elements connected serially between the first input terminal and the second input terminal; and
a common mode voltage being applied to a node between the second and third resistive elements,
wherein a node between the first and second resistive elements and a node between the third and fourth resistive elements provide the stepped-down output signal of the divider circuit.
